(19) United States
(12) Patent Application Publication
(10) Pub. No.: US 2024/0424666 A1
(43) Pub. Date: Dec. 26, 2024

(54) Method for Teaching Transfer Robot and Substrate Processing System

(71) Applicant: Tokyo Electron Limited, Tokyo (JP)

(72) Inventors: Kosuke KINOSHITA, Yamanashi (JP); Takashi Sugimoto, Yamanashi (JP)

(21) Appl. No.: 18/736,055

(22) Filed: Jun. 6, 2024

(30) Foreign Application Priority Data
Jun. 20, 2023 (JP) 2023-100580

(51) Int. Cl. B25J 9/00; B25J 9/04; B25J 11/00; B25J 13/08; B25J 18/04; H01L 21/67; H01L 21/677; H01L 21/68

(52) U.S. Cl. CPC B25J 9/0081; B25J 9/042; B25J 11/0095; B25J 13/088; B25J 18/04; H01L 21/67259; H01L 21/67742; H01L 21/681

(57) ABSTRACT

A method for teaching a transfer robot is provided. The transfer robot includes an arm that rotates around a vertical rotation axis and extends/contracts on a horizontal plane. The arm has a first protrusion disposed on a left side and a second protrusion disposed on a right side. The first protrusion intersects with detection light of a first sensor and the second protrusion intersects with detection light of a second sensor during the extension/contraction of the arm. The method comprises calculating angular deviation of the arm around the rotation axis based on an extension amount of the arm at the time when the second protrusion intersects with the detection light of the second sensor, and the extension amount of the arm at the time when the first protrusion intersects the detection light of the first sensor, and rotating the arm around the rotation axis to eliminate the calculated angular deviation.

### CROSS-REFERENCE TO RELATED APPLICATIONS

This application claims priority to Japanese Patent Application No. 2023-100580 filed on Jun. 20, 2023, the entire contents of which are incorporated herein by reference.

### TECHNICAL FIELD

The present disclosure relates to a method for teaching a transfer robot and a substrate processing system.

### BACKGROUND

In a substrate processing system that performs various processes on a wafer as a substrate, a transfer robot is used for loading/unloading the wafer into/from a substrate processing chamber or a substrate delivery chamber. The transfer robot has an arm capable of rotating around a vertical rotation axis and extending/contracting on a horizontal plane perpendicular to the rotation axis, and a pick that is attached to a tip end of the arm to hold the wafer. The transfer robot is disposed in the substrate transfer chamber adjacent to the substrate processing chamber or the substrate delivery chamber, and load/unloads the wafer by moving the pick into or out of the substrate processing chamber by rotating, extending, and contracting the arm.

In the case of performing various processes on the wafer, it is necessary to accurately place the wafer at a predetermined position on a placing table in the substrate processing chamber. Therefore, it is necessary to accurately recognize the position of the transfer robot for loading/unloading the wafer in the substrate processing chamber or the relative position of the wafer with respect to the transfer robot. The recognition of the relative position of the wafer or the position of the transfer robot is referred to as “teaching” and various methods have been proposed as a method for teaching a transfer robot.

For example, in a processing system disclosed in Japanese Laid-open Patent Publication No. 2021-129023, a horizontal position of a pick of a transfer robot is recognized using a wafer protrusion detection sensor disposed at a loading/unloading port of a substrate transfer chamber to which a transfer container for storing and transferring a plurality of wafers is connected.

In addition, in a substrate processing system disclosed in Japanese Patent No. 6671993, a relative position of a wafer with respect to a transfer robot in a horizontal direction is recognized by sensing passage of the wafer using a sensor disposed at a loading/unloading port located at a boundary between a substrate processing chamber and a substrate transfer chamber.

Further, in a wafer transfer machine disclosed in Japanese Laid-open Patent Publication No. H10-233426, a position of a transfer arm in a rotation direction is recognized by sensing a transfer arm rotating on a horizontal plane using a sensor disposed at an alignment wafer.

### SUMMARY

In view of the above, the technique of the present disclosure eliminates angular deviation of an arm of a transfer robot without requiring any effort.

A type of technology according to the present disclosure is a method for teaching a transfer robot, wherein the transfer robot includes an arm that rotates around a vertical rotation axis and extends/contracts on a horizontal plane perpendicular to the rotation axis, and a substrate support attached to the arm, wherein the arm has a first protrusion disposed on a left side with respect to an extension/contraction direction of the arm, and a second protrusion disposed on a right side with respect to the extension/contraction direction of the arm, the first protrusion and the second protrusion move together with the substrate support by extension/contraction of the arm, a first sensor is disposed on the left side with respect to the extension/contraction direction, and a second sensor is disposed on the right side with respect to the extension/contraction direction, and the first protrusion intersects with detection light of the first sensor during the extension/contraction of the arm, and the second protrusion intersects with detection light of the second sensor during the extension/contraction of the arm, the method comprising: calculating angular deviation of the arm around the rotation axis based on an extension amount of the arm at the time when the second protrusion intersects with the detection light of the second sensor, and the extension amount of the arm at the time when the first protrusion intersects the detection light of the first sensor; and rotating the arm around the rotation axis to eliminate the calculated angular deviation.

### BRIEF DESCRIPTION OF THE DRAWINGS

FIG. 1 is a plan view showing a configuration of a substrate processing system including a transfer robot according to an embodiment of a technique of the present disclosure.

FIGS. 2A and 2B are plan views for explaining a configuration of a transfer robot disposed in a transfer module in FIG. 1.

FIG. 3 is a perspective view for explaining a configuration of a wafer detection sensor (AWC sensor) in FIG. 1.

FIG. 4 explains the positional relationship between a pick attached to an arm of a transfer robot and an AWC sensor.

FIGS. 5A to 5D explain intersection of a left protrusion, a right protrusion, and laser beam of an AWC sensor at the time when the arm of the transfer robot is extended.

FIGS. 6A to 6D explain the reason why a left shielding distance and a right shielding distance are not equal in the case where the angular deviation of the arm of the transfer robot has occurred.

FIGS. 7A to 7C explain a method of calculating angular deviation of an arm of a transfer robot.

FIGS. 8A to 8D explain a case where the arm of the transfer robot is deviated from a design value in a clockwise direction.

FIGS. 9A to 9D explain the advantage of an inclined side of a left protrusion or a right protrusion of a pick.

FIG. 10 is a flowchart showing a process for correcting angular deviation of an arm, as a method for teaching a transfer robot according to an embodiment of the technique of the present disclosure.

FIG. 11 shows a modification of a pick.

### DETAILED DESCRIPTION

In a substrate transfer chamber adjacent to a substrate processing chamber where plasma processing is performed on a wafer in a decompressed environment, a transfer robot is installed such that a position of the transfer robot in the substrate transfer chamber is not deviated from a design value. However, if the substrate transfer chamber is decompressed after the transfer robot is installed, so-called angular deviation in which a direction of an arm of the transfer robot is deviated from the design value in the rotation direction may occur due to slight deformation of the substrate transfer chamber due to the decompression.

As a method for eliminating the angular deviation, there is known a method in which an operator visually recognizes (measures) angular deviation of an arm through a window from the outside and rotates the arm to eliminate the recognized angular deviation. In addition, as a method that does not rely on an operator's visual recognition, the teaching method disclosed in Japanese Patent Application Publication No. H10-233426 may be applied to measure the angular deviation of the arm by recognizing the position of the arm of the transfer robot in the rotation direction. Also in this case, the arm is rotated to eliminate the measured angular deviation.

Since the former requires an operator's visual recognition and the latter requires an alignment wafer having a sensor, both teaching methods require efforts.

In contrast, the technique of the present disclosure eliminates angular deviation of an arm without efforts.

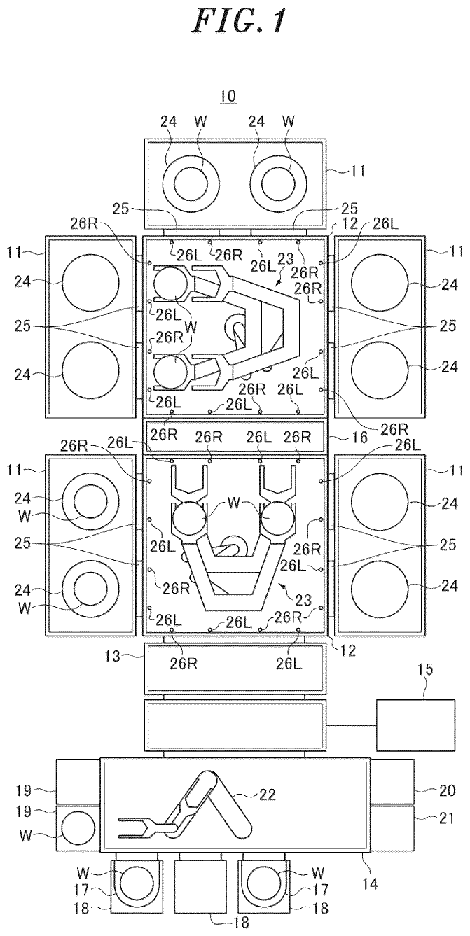

Hereinafter, one embodiment of the technique according to the present disclosure will be described with reference to the accompanying drawings. FIG. 1 is a plan view showing a configuration of a substrate processing system including a transfer robot according to the embodiment. Further, in FIG. 1, for the sake of convenience, the internal components of some devices are shown as being visible.

In FIG. 1, a substrate processing system 10 includes five process modules 11 (substrate processing chambers), two transfer modules 12 (substrate transfer chambers), a load-lock module 13, a loader module 14, and a controller 15. The controller 15 controls operations of individual components of the substrate processing system 10.

The plurality of process modules 11 are connected to each transfer module 12, and a substrate delivery chamber 16 is disposed between the two transfer modules 12. Further, the load-lock module 13 is disposed between one transfer module 12 and the loader module 14.

In the loader module 14, a load port 18 that is a placing table for a front opening unified pod (FOUP) 17 that is a transfer container for a plurality of wafers Was substrates is disposed. Further, in the loader module 14, a wafer storage 19 for temporarily storing each wafer W, an aligner 20 for adjusting a position of the wafer W, and a mapping temporary base (MTB) 21 as a temporary storage area for the wafer W are disposed.

The loader module 14 is a housing maintained in an atmospheric pressure atmosphere, and has a transfer robot 22 that is movable therein. The transfer robot 22 transfers the wafer W between the FOUP 17, the wafer storage 19, the aligner 20, the MTB 21, and the load-lock module 13.

The load-lock module 13 temporarily holds the wafer W when the wafer W is transferred between the loader module 14 maintained in an atmospheric pressure atmosphere and the transfer module 12 maintained in a vacuum atmosphere. The load-lock module 13 is configured such that an inner atmosphere thereof can be switched between an atmospheric pressure atmosphere and a vacuum atmosphere. The inner atmosphere of the load-lock module 13 is maintained in an atmospheric pressure atmosphere when the wafer W is transferred to/from the loader module 14, and is maintained in a vacuum atmosphere when the wafer W is transferred from/to the transfer module 12.

As described above, the transfer module 12 is maintained in a vacuum atmosphere, and has therein the transfer robot 23. The transfer robot 23 transfers the wafer W between each process module 11, the substrate delivery chamber 16, and the load-lock module 13.

The process module 11 is maintained in a vacuum atmosphere, and has therein a placing table 24 for placing a wafer W. The process module 11 performs various decompression processes, e.g., plasma processing such as etching, film formation, and the like, on the placed wafer W. In the present embodiment, the process module 11 has two placing tables 24, so that various decompression processes are performed on two wafers W at the same time. Accordingly, the transfer robot 23 of the transfer module 12 transfers two wafers W at the same time.

In the case of performing various decompression processes on the wafer W, it is necessary to partition the inside of the process module 11 from the inside of the transfer module 12, so that a gate valve 25 that can be opened and closed is disposed between the transfer module 12 and the process module 11. The gate valve 25 is disposed to correspond to each placing table 24.

In the substrate processing system 10, when various decompression processes are performed on the wafer W, it is necessary to accurately place the wafer W on a designed position of the placing table 24 of the process module 11. Therefore, in the case of loading the wafers W into the process module 11, it is necessary to accurately recognize the position of each wafer W. Hence, wafer detection sensors (hereinafter, referred to as “AWC sensors”) 26L and 26R for sensing the wafers W are disposed in the transfer module 12. The AWC sensors 26L and 26R are disposed to correspond to the gate valves 25. The AWC sensor 26L is disposed on the left side with respect to the transfer direction of the wafer W by the transfer robot 23. The AWC sensor 26L is disposed on the right side with respect to the transfer direction of the wafer W by the transfer robot 23. The AWC sensors 26L and 26R are disposed at the substrate processing system 10 in advance to sense the wafers W regardless of whether or not the technique of the present disclosure is applied.

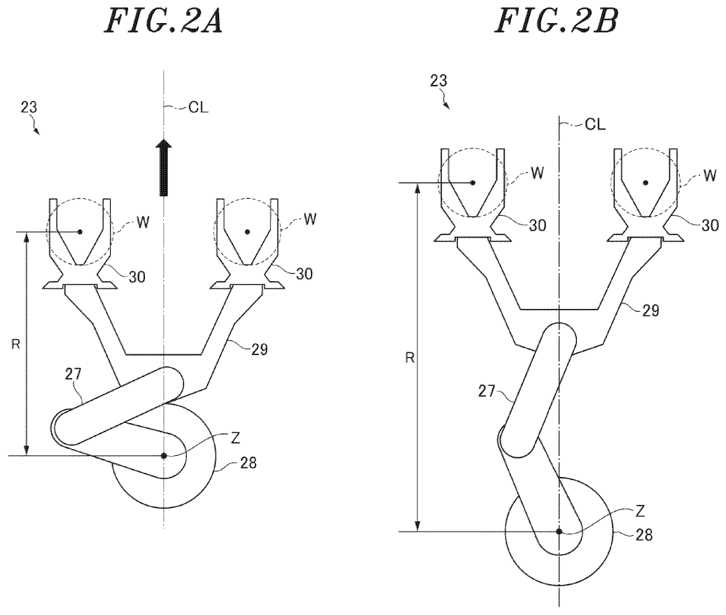

FIGS. 2A and 2B are plan views for explaining the configuration of the transfer robot 23 disposed in the transfer module 12. The transfer robot 23 includes a horizontal multi-joint (SCARA) type arm 27, a base 28 to which one end of the arm 27 is attached, a bifurcated fork 29 attached to the other end of the arm 27, and two picks 30 (substrate holders) attached to the tip end of the fork 29. In the transfer robot 23, the arms 27 are arranged at two stages in the vertical direction. However, in FIGS. 2A and 2B, only one arm 27 is illustrated for ease of understanding.

Each of the two picks 30 holds the wafer W. The arm 27 is attached to the base 28 to be rotatable around a vertical rotation axis Z. Further, the arm 27 is stretched/bent to extend/contract on a horizontal plane perpendicular to the rotation axis Z. FIG. 2A shows a state in which the arm 27 is contracted, and FIG. 2B shows a state in which the arm 27 is extended.

When the arm 27 is extended and contracted, the fork 29 moves without shaking leftward and rightward with respect to the direction (indicated by a black arrow in FIG. 2A) in which the arm 27 is extended/contracted, and the fork 29 does not rotate. Therefore, the two picks 30 also move without shaking leftward and rightward with respect to the direction in which the arm 27 is extended/contracted, and do not rotate. Accordingly, the transfer robot 23 can linearly transfer each wafer W along the extension/contraction direction. Further, by rotating the arm 27 around the rotation axis Z, the transfer robot 23 can change the transfer direction of each wafer W. Hereinafter, the direction in which the arm 27 is extended/contracted will be simply referred to as “extension/contraction direction.” The transfer robot 23 freely transfers the wafer W between each process module 11, the substrate delivery chamber 16, and the load-lock module 13 by combining rotation and extension/contraction of the arm 27.

In the transfer robot 23, the fork 29 has a symmetrical shape with respect to a center line CL of the transfer robot 23 (the arm 27) along the extension/contraction direction, and the two picks 30 are arranged in symmetrical positions with respect to the center line CL.

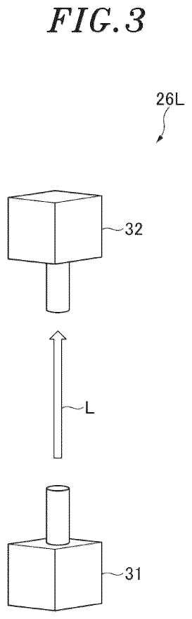

FIG. 3 is a perspective view for explaining the configuration of the AWC sensors 26L and 26R. Since the AWC sensor 26R has the same configuration as that of the AWC sensor 26L, only the AWC sensor 26L is shown in FIG. 3, and the description of the AWC sensor 26R will be omitted.

In FIG. 3, the AWC sensor 26L has a light emitting part 31 and a light receiving part 32. The light emitting part 31 emits laser light L (detection light) toward the light receiving part 32, and the light receiving part 32 receives the laser light L. When the arm 27 is extended and the wafer W held by the pick 30 passes through the gap between the light emitting part 31 and the light receiving part 32, the light receiving part 32 does not receive the laser light L when the wafer W starts to intersect with the laser light L, so that the light receiving part 32 transmits an OFF signal to the controller 15. Further, the light receiving part 32 starts to receive the laser beam L again when the wafer W has passed through the gap between the light emitting part 31 and the light receiving part 32 and the wafer W no longer intersects with the laser beam L, so that the light receiving part 32 transmits an ON signal to the controller 15.

The controller 15 calculates the extension amount of the arm 27 at the time of receiving the OFF signal or the ON signal, for example, the extension/contraction distance from the rotation axis Z to the central position in the extension/contraction direction of the pick 30. This distance is calculated, e.g., from an encoder value of a motor (not shown) for driving the arm 27 of the transfer robot 23. Hereinafter, the extension/contraction distance from the rotation axis Z to the center position in the extension/contraction direction of the pick 30 will be defined as “extension amount of the arm 27.” In this case, the extension amount of the arm 27 corresponds to a distance indicated by “R” in FIG. 2A or 2B. However, the extension amount of the arm 27 is not limited to the extension/contraction distance from the rotation axis Z to the central position in the extension/contraction direction of the pick 30, and may be any amount that changes by the extension of the arm 27.

The controller 15 may obtain the extension amount of the arm 27 at the time when the intersection between the laser beam L and the wafer W held at a correct position without deviation with respect to the pick 30 is started based on the design of the substrate processing system 10 or the like. Similarly, the controller 15 may obtain the extension amount of the arm 27 at the time when the intersection between the laser beam L and the wafer W held at a correct position without deviation with respect to the pick 30 is ended.

The controller 15 may obtain the positional deviation of the wafer W with respect to the pick 30 based on the comparison between the extension amount of the arm 27 at the time of receiving an OFF signal and the extension amount of the arm 27 at the time of receiving an ON signal. Accordingly, the relative position of the wafer W with respect to the arm 27 can also be obtained.

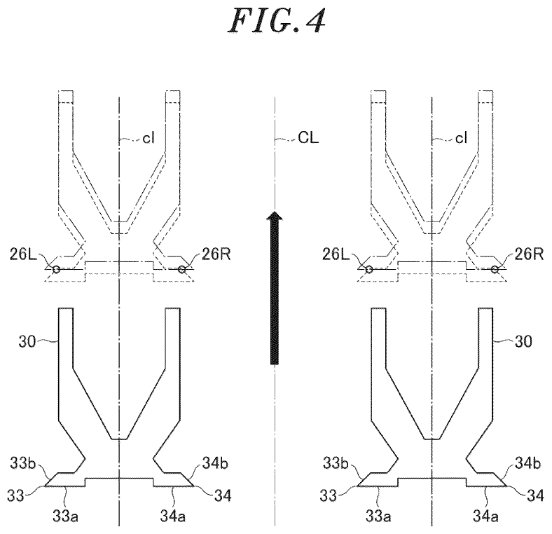

Further, in the present embodiment, as shown in FIG. 4, each pick 30 includes a left protrusion 33 (first protrusion) disposed on the left side with respect to the extension/contraction direction, and a right protrusion 34 (second protrusion) disposed on the right side with respect to the extension/contraction direction. The left protrusion 33 and the right protrusion 34 move together with the pick 30 by the extension/contraction of the arm 27.

The left protrusion 33 of the pick 30 has a rear end side 33a stretched on a horizontal plane perpendicular to the rotation axis Z and extending in a direction perpendicular to the extension/contraction direction, and an inclined side 33b (first inclined side) intersecting obliquely with a direction perpendicular to the extension/contraction direction. The right protrusion 34 of the pick 30 has a rear end side 34a stretched on a horizontal plane perpendicular to the rotation axis Z and extending in a direction perpendicular to the extension/contraction direction, and an inclined side 34b (second inclined side) intersecting obliquely with a direction perpendicular to the extension/contraction direction.

Further, in each pick 30, the left protrusion 33 and the right protrusion 34 are symmetrical with respect to the center line CL along the extension/contraction direction of the pick 30. Here, as described above, the two picks 30 are arranged at symmetrical positions with respect to the center line CL. Therefore, the left protrusion 33 of the left pick 30 and the right protrusion 34 of the right pick 30 are also symmetrical with respect to the center line CL.

As described above, the AWC sensors 26L and 26R are arranged to correspond to the respective gate valves 25. Each gate valve 25 is disposed on the path where each pick 30 moves when the arm 27 is extended. Therefore, the AWC sensors 26L and 26R are also disposed on the movement path of the pick 30.

When the pick 30 moves, the left protrusion 33 intersects with the laser beam L of the AWC sensor 26L, and the right protrusion 34 intersects with the laser beam L of the AWC sensor 26R. Further, the AWC sensor 26L (first sensor) corresponding to the left pick 30 and the AWC sensor 26R (second sensor) corresponding to the right pick 30 are designed to be located at symmetrical positions with respect to the center line CL. Further, hereinafter, the AWC sensor 26L corresponding to the left pick 30 will be referred to as “left AWC sensor 26L” and the AWC sensor 26R corresponding to the right pick 30 will be referred to as “right AWC sensor 26R.”

When the left pick 30 moves, the left protrusion 33 of the left pick 30 first intersects with the laser beam L of the left AWC sensor 26L. When the left pick 30 moves further, the left protrusion 33 of the left pick 30 no longer intersects with the laser beam L of the left AWC sensor 26L. Further, when the right pick 30 moves, the right protrusion 34 of the right pick 30 first intersects with the laser beam L of the right AWC sensor 26R. When the right pick 30 moves further, the right protrusion 34 of the right pick 30 no longer intersects with the laser beam L of the right AWC sensor 26R.

In FIG. 4, for reference, dashed lines indicate the pick 30 at the time when the left protrusion 33 of the left pick 30 starts to intersect with the laser beam L of the left AWC sensor 26L and the pick 30 at the time when the right protrusion 34 of the right pick 30 starts to intersect with the laser beam L of the right AWC sensor 26R. Further, dashed dotted lines indicate the pick 30 at the time when the left protrusion 33 of the left pick 30 no longer intersects with the laser beam L of the left AWC sensor 26L and the pick 30 at the time when the right protrusion 34 of the right pick 30 no longer intersects with the laser beam L of the right AWC sensor 26R.

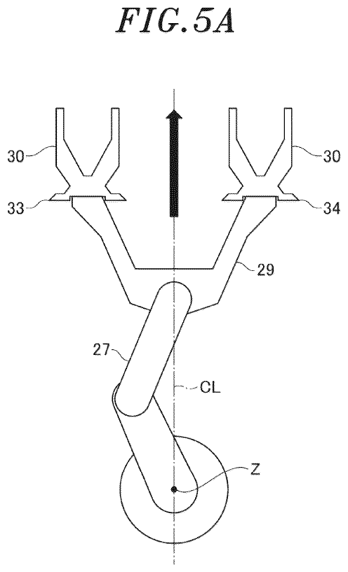

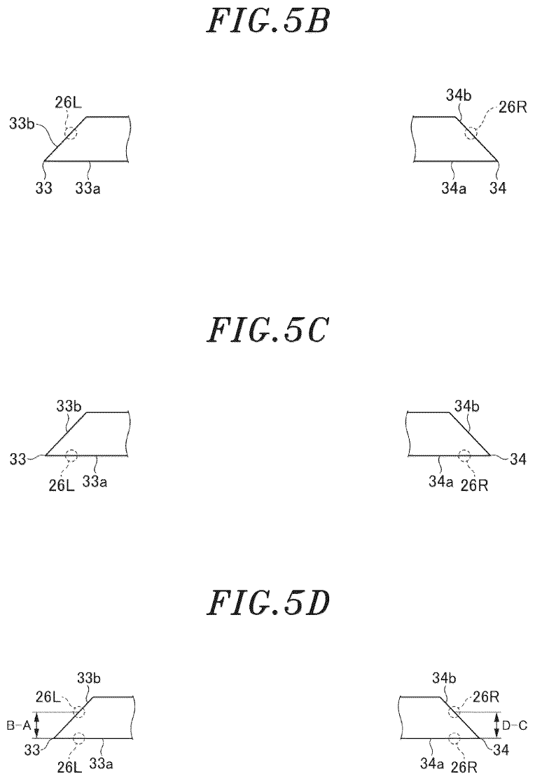

FIGS. 5A to 5D explain the intersection between the left protrusion 33 and the laser beam L of the left AWC sensor 26L and the intersection between the right protrusion 34 and the laser beam L of the right AWC sensor 26R at the time when the arm 27 of the transfer robot 23 is extended. Further, hereinafter, the laser light L of the left AWC sensor 26L will be simply referred to as “left laser light L” and the laser light L of the right AWC sensor 26R will be simply referred to as “right laser light L.”

When the arm 27 is extended as shown in FIG. 5A, the left protrusion 33 of the left pick 30 first starts to intersect with the left laser beam L as shown in FIG. 5B. In this case, the inclined side 33b of the left protrusion 33 intersects with the left laser beam L and, then, the laser beam L is blocked by the left protrusion 33. Therefore, an OFF signal is transmitted from the light receiving part 32 at the timing when the inclined side 33b of the left protrusion 33 intersects with the left laser beam L, and the controller 15 calculates the extension amount of the arm 27 at this time. Hereinafter, the extension amount of the arm 27 calculated at this time will be referred to as “shielding start position A” of the left protrusion 33.

Further, when the left pick 30 moves further, the intersection between the left protrusion 33 and the left laser beam L is ended as shown in FIG. 5C. In this case, the rear end side 33a of the left protrusion 33 intersects with the left laser beam L and, then, the laser beam L is not blocked by the left protrusion 33. Therefore, an ON signal is transmitted from the light receiving part 32 at the timing when the rear end side 33a of the left protrusion 33 intersects with the left laser beam L, and the controller 15 calculates the extension amount of the arm 27 at this timing. Hereinafter, the extension amount of the arm 27 calculated at this time will be referred to as “shielding end position B” of the left protrusion 33.

Further, when the arm 27 is extended as shown in FIG. 5A, the right protrusion 34 of the right pick 30 first starts to intersect with the right laser beam L as shown in FIG. 5B. In this case, the inclined side 34b of the right protrusion 34 intersects the right laser beam L and, then, the laser beam L is blocked by the right protrusion 34. Therefore, the OFF signal is transmitted from the light receiving part 32 at the timing when the inclined side 34b of the right protrusion 34 intersects the right laser beam L, and the controller 15 calculates the extension amount of the arm 27 at this time. Hereinafter, the extension amount of the arm 27 calculated at this time will be referred to as “shielding start position C” of the right protrusion 34.

Further, when the right pick 30 moves further, the intersection between the right protrusion 34 and the right laser beam L is ended as shown in FIG. 5C. In this case, the rear end side 34a of the right protrusion 34 intersects the right laser beam L and, then, the laser beam L is not blocked by the right protrusion 34. Therefore, an ON signal is transmitted from the light receiving part 32 at the timing when the rear end side 34a of the right protrusion 34 intersects with the right laser beam L, and the controller 15 calculates the extension amount of the arm 27 at this timing. Hereinafter, the extension amount of the arm 27 calculated at this time will be referred to as “shielding end position D” of the right protrusion 34.

While the arm 27 is being extended from the shielding start position A to the shielding end position B, the left protrusion 33 of the left pick 30 continues to shield the left laser beam L. Therefore, the difference (B-A) between the shielding end position B and the shielding start position A of the left protrusion 33 is equal to the distance in which the arm 27 moves in a state where the left laser beam L is shielded by the left protrusion 33. Further, while the arm 27 is being extended from the shielding start position C to the shielding end position D, the right protrusion 34 of the right pick 30 continues to shield the right laser beam L. Therefore, the difference (D-C) between the shielding end position D and the shielding start position C of the right protrusion 34 is equal to the distance in which the arm 27 moves in a state where the right laser beam L is shielded by the right protrusion 34. Hence, hereinafter, the difference between the shielding end position B and the shielding start position A of the left protrusion 33 will be referred to as “left shielding distance (B-A)” (first distance), and the difference between the shielding end position D and the shielding start position C of the right protrusion 34 will be referred to as “left shielding distance (D-C)” (second distance).

Here, when the direction of the arm 27 of the transfer robot 23 with respect to the rotation direction is not deviated from the design value, the timing at which the inclined side 33b of the left protrusion 33 intersects with the left laser beam L coincides with the timing at which the inclined side 34b of the right protrusion 34 intersects with the right laser beam L. Further, the timing at which the rear end side 33a of the left protrusion 33 intersects with the left laser beam L coincides with the timing at which the rear end side 34a of the right protrusion 34 intersects with the right laser beam L. Hence, in this case, the shielding start position A of the left protrusion 33 and the shielding start position C of the right protrusion 34 coincide with each other, and the shielding end position B of the left protrusion 33 and the shielding end position D of the right protrusion 34 also coincide with each other. As a result, the left shielding distance (B-A) and the right shielding distance (D-C) are equal to each other (see FIG. 5D). Hereinafter, the angular deviation of the arm 27 around the rotation axis Z will be simply referred to as “angular deviation of the arm 27” and “the case where the direction of the arm 27 of the transfer robot 23 with respect to the rotation direction is not deviated from the design value” will be referred to as “the case where the angular deviation of the arm 27 has not occurred.”

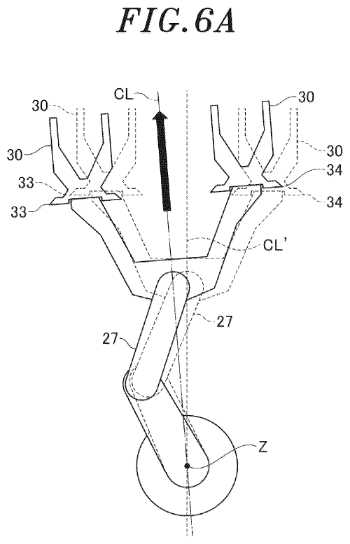

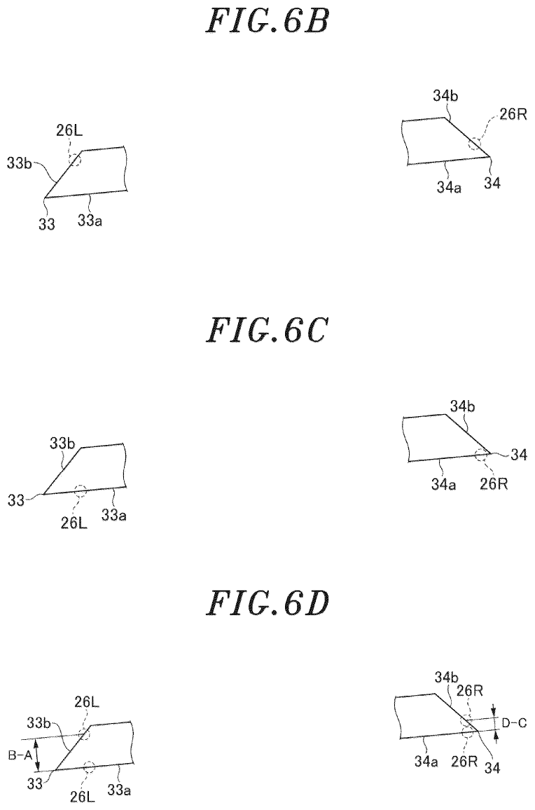

On the other hand, when the angular deviation of the arm 27 has occurred, the left shielding distance (B-A) and the right shielding distance (D-C) are not equal to each other. FIGS. 6A to 6D explain the reason why the left shielding distance (B-A) and the right shielding distance (D-C) are not equal to each other in the case where the angular deviation of the arm 27 has occurred. In FIGS. 6A to 6D, the transfer robot 23 including the arm 27 that is deviated in the counterclockwise direction is indicated by a solid line, and the transfer robot 23 including the arm 27 without angular deviation is indicated by a dashed line.

For example, as shown in FIG. 6A, when the arm 27 is deviated from the design value in a counterclockwise direction, the center line CL along the actual extension/contraction direction of the arm 27 is inclined to the left side with respect to a center line CL′ along a designed extension/contraction direction. Therefore, the left pick 30 and the right pick 30 are offset to the left side from the designed positions. On the other hand, the left AWC sensor 26L and the right AWC sensor 26R are arranged at symmetrical positions with respect to a center line CL′ along the designed extension/contraction direction. Hence, the left protrusion 33 of the left pick 30 is offset to the left side with respect to the left AWC sensor 26L, and the right protrusion 34 of the right pick 30 is also offset to the left side with respect to the right AWC sensor 26R.

In this case, when the arm 27 is extended, the left laser beam L intersects on the right side compared to when there is no angular deviation between the arm 27 and the inclined side 33b of the left protrusion 33 of the left pick 30 (see FIG. 6B). Further, the left laser beam L intersects on the right side compared to when there is no angular deviation between the arm 27 and the rear end side 33a of the left protrusion 33 (see FIG. 6C)). Here, the left protrusion 33 becomes thicker (the width in the extension/contraction direction becomes larger) toward the right side due to the presence of the inclined side 33b, so that the left shielding distance (B-A) becomes longer compared to when the angular deviation of the arm 27 has not occurred (see FIG. 6D).

Further, when the arm 27 is extended, the right laser beam L intersects on the right side compared to when there is no angular deviation between the arm 27 and the inclined side 34b of the right protrusion 34 of the right pick 30 (see FIG. 6B). Further, the right laser beam L intersects on the right side compared to when there is no angular deviation between the arm 27 and the rear end side 34a of the right protrusion 34 (see FIG. 6C). Here, the right protrusion 34 becomes thinner (the width in the direction of extension and contraction becomes smaller) toward the right side due to the presence of the inclined side 34b, so that the right shielding distance (D-C) becomes smaller compared to when the angular deviation of the arm 27 has not occurred (see FIG. 6D).

In other words, when the angular deviation of the arm 27 has occurred, the left shielding distance (B-A) and the right shielding distance (D-C) are not equal to each other, and the left shielding distance (B-A) or the right shielding distance (D-C) changes compared to when the angular deviation of the arm 27 has not occurred. In the present embodiment, the angular deviation of the arm 27 is calculated using the change in the left shielding distance (B-A) or the right shielding distance (D-C).

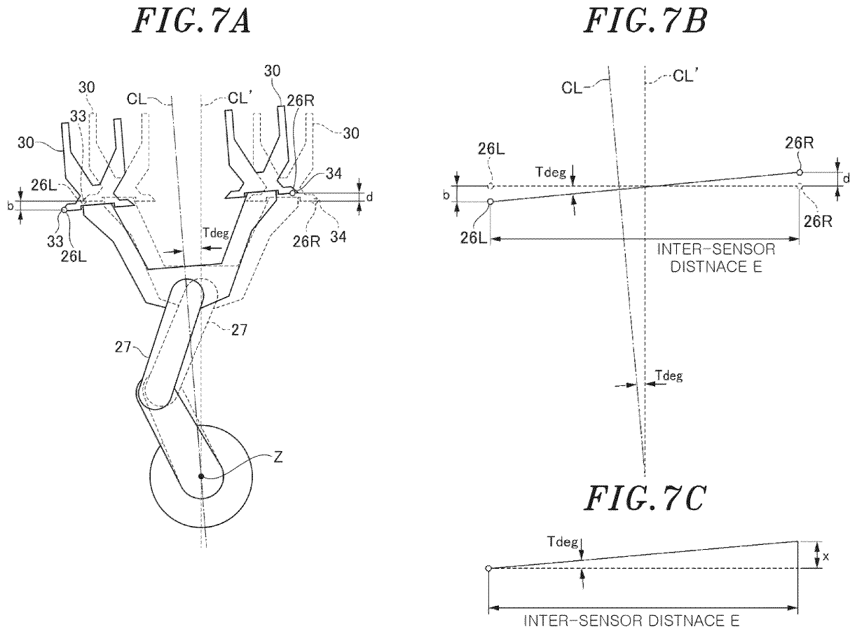

FIGS. 7A to 7C explain a method for calculating angular deviation of the arm 27 of the transfer robot 23. Also in FIGS. 7A to 7C, the transfer robot 23 including the arm 27 that is deviated from the design value in a counterclockwise direction is indicated by a solid line, and the transfer arm 23 including the arm 27 without angular deviation is indicated by a dashed line.

In this case, as described above, the left shielding distance (B-A) becomes longer compared to when the angular deviation of the arm 27 has not occurred. As shown in FIG. 7A, the increase in the left shielding distance (B-A) corresponds to a difference b between the shielding end positions B of the left protrusion 33 between when the angular deviation of the arm 27 has not occurred and when the angular deviation of the arm 27 has occurred. Further, as described above, the right shielding distance (D-C) becomes shorter compared to when the angular deviation of the arm 27 has not occurred. As shown in FIG. 7A, the decrease in the right shielding distance (D-C) corresponds to a difference d of the shielding end positions D of the right protrusion 34 between when the angular deviation of the arm 27 has not occurred and when the angular deviation of the arm 27 has occurred.

Here, the magnitude of the angular deviation is T (deg), and the pitch between the left AWC sensor 26L and the right AWC sensor 26R is E (hereinafter, referred to as “inter-sensor distance E”). In this case, the magnitude T of the angular deviation, the difference b between the shielding end positions B, the difference d between the shielding end positions D, and the inter-sensor distance E approximately satisfy the geometrical relationship shown in FIG. 7B.

If the sum of the difference b between the shielding end positions B and the difference d between the shielding end positions D is set to a distance x, the geometric relationship shown in FIG. 7C is approximately satisfied between the magnitude T of the angular deviation, the distance x, and the inter-sensor distance E. Here, since the angular deviation of the arm 27 due to slight deformation of the transfer module 12 by decompression is considered to be small, the tangent of the magnitude T (deg) of the angular deviation can be approximated to the magnitude T (rad) of the angular deviation. Therefore, the following Eq. (1) is satisfied between the magnitude T (deg) of the angular deviation magnitude, the distance x, and the inter-sensor distance E.

$$x = 2 π \times \frac{T}{360} \times E \qquad Eq . ( 1 )$$

Since the left AWC sensor 26L and the right AWC sensor 26R are arranged at symmetrical positions with respect to the center line CL′ along the designed extension/contraction direction, it is considered that the difference b between the shielding end position B and the difference d between the shielding end position D are equal to each other, and are equal to a half of the distance x. Accordingly, the following Eqs. (2) and (3) are satisfied.
Eq. (2)
the difference b between the shielding end positions B of the left protrusion

$$33 = \frac{x}{2} = π \times \frac{T}{360} \times E \qquad Eq . ( 3 )$$

the difference d between the shielding end positions D of the right protrusion

$$34 = \frac{x}{2} = π \times \frac{T}{360} \times E$$

Further, the following Eq. (4) is satisfied between the shielding end position B in the case where the angular deviation of the arm 27 has occurred and a shielding end position B′ (the assumed extension amount of the first arm) in the case where it is assumed that the angular deviation of the arm 27 has not occurred.
Eq. (4)
the shielding end position B′=the difference b between the shielding end positions B=the shielding end position

$$B - π \times \frac{T}{360} \times E$$

Further, the following Eq. (5) is satisfied between the shielding end position D in the case where the angular deviation of the arm 27 has occurred and a shielding end position D′ (the assumed extension amount of the second arm) in the case where it is assumed that the angular deviation of the arm 27 has not occurred.
Eq. (5)
the shielding end position D′=the difference d between the shielding end positions D=the shielding end position

$$D + π \times \frac{T}{360} \times E$$

The following Eq. (6) is satisfied because it is considered that the difference between the shielding start position A and the shielding end position B′ of the left protrusion 33 (the left shielding distance (B′−A)) is equal to the difference between the shielding start position C and the shielding end position D′ of the right protrusion 34 (the right shielding distance (D′−C)).
Eq. (6)
the shielding end position B′—the shielding start position A=the shielding end position D′—the shielding start position C

When Eqs. (4) and (5) are substituted into Eq. (6), the magnitude T (deg) of the angular deviation is expressed by the following Eq. (7). Here, the shielding start position A, the shielding end position B, the shielding start position C, and the shielding end position D are the actually measured values in the case where the angular deviation of the arm 27 has occurred.

$$Eq . ( 7 )$$

$$T = \frac{360}{2 π \times E} \times ( ( ( the shielding end position B - the shielding start position A ) ) - ( ( the shielding end position D - the shielding start position C ) ) )$$

Further, the following Eq. (8) is obtained by replacing the shielding end position B−the shielding start position A with the left shielding distance (B−A), and replacing the shielding end position D−the shielding start position C with the right shielding distance (D−C).

$$Eq . ( 8 )$$

$$T = \frac{360}{2 π \times E} \times ( ( ( the left shielding distance ( B - A ) ) - ( ( the right shielding distance ( D - C ) ) )$$

In this manner, the magnitude T of the angular deviation of the arm 27 of the transfer robot 23 can be calculated based on the left shielding distance (B−A), the right shielding distance (D−C), and the inter-sensor distance E.

Further, in order to eliminate the angular deviation of the arm 27 using the magnitude T of the angular deviation of the arm 27 calculated as described above, it is necessary to determine whether the arm 27 is deviated in a clockwise direction or in counterclockwise direction.

Here, as shown in FIGS. 6A to 6D, if the arm 27 is deviated from the design value in a counterclockwise direction, the left shielding distance (B−A) becomes longer compared to when the angular deviation of the arm 27 has not occurred. Further, the right-shielding distance (D−C) becomes shorter compared to when the angular deviation of the arm 27 has not occurred. In other words, if the arm 27 is deviated from the design value in a counterclockwise direction, the left shielding distance (B−A) becomes longer than the right shielding distance (D−C).

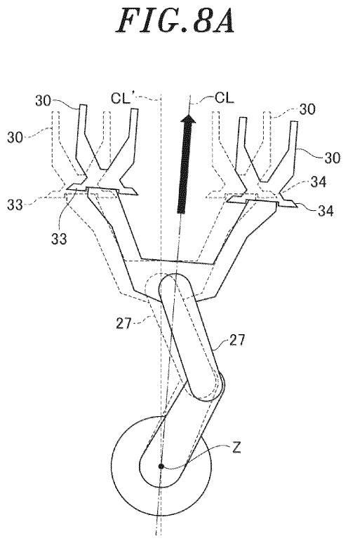

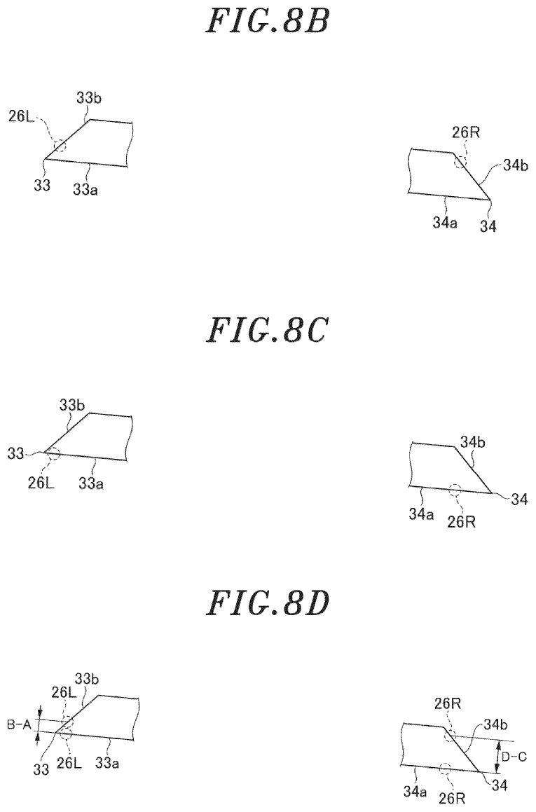

On the other hand, as shown in FIG. 8A, when the arm 27 is deviated from the design value in a clockwise direction, the center line CL along the actual extension/contraction direction of the arm 27 is inclined to the right side with respect to the center line CL′ along the designed extension/contraction direction. Therefore, the left pick 30 and the right pick 30 are offset to the right side from the designed positions. As a result, the left protrusion 33 of the left pick 30 is offset to the right side with respect to the left AWC sensor 26L, and the right protrusion 34 of the right pick 30 is also offset to the right side with respect to the right AWC sensor 26R.

In this case, when the arm 27 is extended, the left laser beam L intersects on the left side compared to when there is no angular deviation between the arm 27 and the inclined side 33b of the left protrusion 33 of the left pick 30 (see FIG. 8B). Further, the left laser beam L intersects on the left side compared to when there is no angular deviation between the arm 27 and the rear end side 33a of the left protrusion 33 (see FIG. 8C). Here, the left protrusion 33 becomes thinner toward the left side due to the presence of the inclined side 33b, so that the left shielding distance (B−A) becomes shorter compared to when the angular deviation of the arm 27 has not occurred (see FIG. 8D).

Further, when the arm 27 is extended, the right laser beam L intersects on the left side compared to when there is no angular deviation between the arm 27 and the inclined side 34b of the right protrusion 34 of the right pick 30 (see FIG. 8B). Further, the right laser beam L intersects on the left side compared to the case where there is no angular deviation between the arm 27 and the rear end side 34a of the right protrusion 34 (see FIG. 8C). Here, the right protrusion 34 becomes thicker toward the left side due to the presence of the inclined side 34b, so that the right shielding distance (D−C) becomes longer compared to when the angular deviation of the arm 27 has not occurred (see FIG. 8D).

In other words, when the arm 27 is deviated from the design value in a clockwise direction, the right shielding distance (D−C) becomes longer than the left shielding distance (B−A).

Therefore, in the present embodiment, the direction of the angular deviation of the arm 27 can be determined based on the right shielding distance (D−C) and the left shielding distance (B−A). Specifically, when the left shielding distance (B−A) is longer than the right shielding distance (D−C), it can be determined that the arm 27 is deviated from the design value in a counterclockwise direction. Further, when the right shielding distance (D−C) is longer than the left shielding distance (B−A), it can be determined that the arm 27 is deviated from the design value in a clockwise direction.

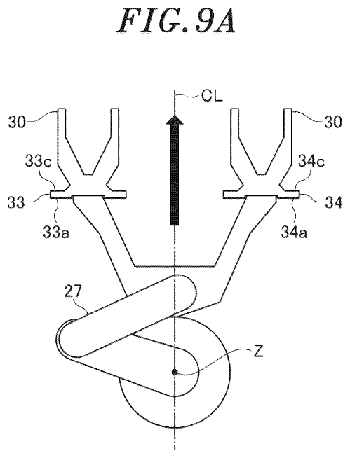

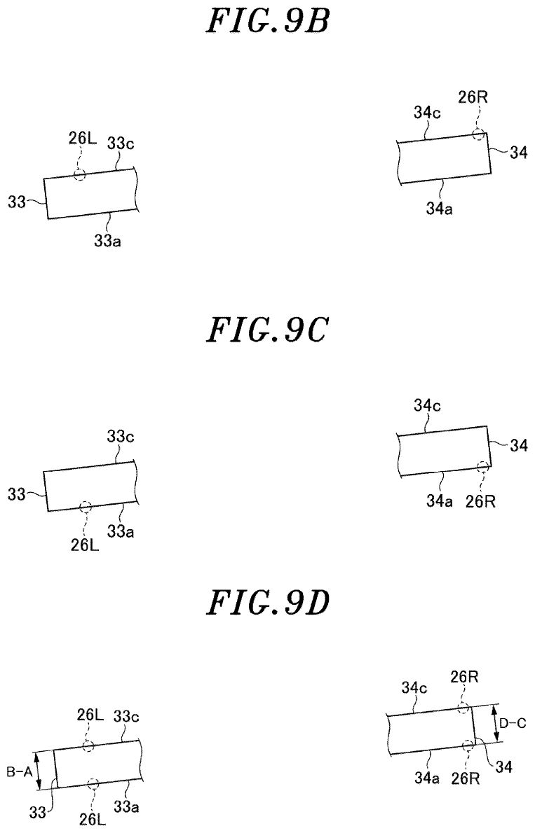

FIGS. 9A to 9D explain the advantage of the inclined sides 33b and 34b of the left protrusion 33 and the right protrusion 34 of the pick 30.

Here, the case shown in FIG. 9A in which the left protrusion 33 and the right protrusion 34 of the pick 30 do not have the inclined sides 33b and 34b, and the left protrusion 33 and the right protrusion 34 have a rectangular shape in plan view, for example, will be examined. In this case, the left protrusion 33 has a front end side 33c extending in a direction perpendicular to the extension/contraction direction, instead of the inclined side 33b, and the right protrusion 34 has a front end side 33c extending in a direction perpendicular to the extension/contraction direction, instead of the inclined side 34b.

Also in this case, if the arm 27 is deviated from the design value in a counterclockwise direction, the left protrusion 33 of the left pick 30 is offset to the left side with respect to the left AWC sensor 26L, and the right protrusion 34 of the right pick 30 is offset to the left side with respect to the left AWC sensor 26R.

Then, when the arm 27 is extended, the left laser beam L intersects on the right side compared to when there is no angular deviation between the arm 27 and the front end side 33c of the left protrusion 33 of the left pick 30 (see FIG. 9B). Further, the left laser beam L intersects on the right side compared to when there is no angular deviation between the arm 27 and the rear end side 33a of the left protrusion 33 (see FIG. 9C). Since the rear end side 33a and the front end side 33c extend parallel to each other, the left protrusion 33 does not become thicker toward the right side, and the width thereof in the extension/contraction direction does not change. Therefore, the left shielding distance (B−A) is the same as that in the case where the angular deviation of the arm 27 has not occurred (see FIG. 9D).

Further, when the arm 27 is extended, the right laser beam L intersects with the front end side 34c of the right protrusion 34 of the right pick 30 on the right side compared to when the angular deviation of the arm 27 has not occurred (see FIG. 9B). Further, the right laser beam L intersects with the rear end side 34a of the same right protrusion 34 on the right side compared to when the angular deviation of the arm 27 has not occurred (see FIG. 9C). Since the rear end side 34a and the front end side 34c also extend parallel to each other, the right protrusion 34 does not become thinner toward the right side, and the width thereof in the extension/contraction direction does not change. Therefore, the right shielding distance (D−C) is also the same as that in the case where the angular deviation of the arm 27 has not occurred (see FIG. 9D).

In the present embodiment, the angular deviation of the arm 27 is calculated using the change in the left shielding distance (B−A) and the right shielding distance (D−C). On the other hand, as described above, the left shielding distance (B−A) or the right shielding distance (D−C) does not change if the left protrusion 33 and the right protrusion 34 of the pick 30 do not have the inclined sides 33b and 34b, so that it is substantially not possible to calculate the angular deviation of the arm 27. In other words, the transfer robot 23 is advantageous in that the angular deviation of the arm 27 can be calculated due to the presence of the inclined sides 33b and 34b of the left protrusion 33 and the right protrusion 34.

In the present embodiment, the intersection angle of the inclined side 33b of the left protrusion 33 or the inclined side 34b of the right protrusion 34 with respect to the direction perpendicular to the extension/contraction direction is set to, e.g., 45°. However, the intersection angle is not limited thereto, and may be an angle at which the thickness of the left protrusion 33 or the right protrusion 34 changes along the direction perpendicular to the extension/contraction direction. The intersection angle may be, e.g., 30° or 60°. Since the change in the left shielding distance (B−A) or the right shielding distance (D−C) increase as the intersection angle increases, it is preferable that the intersection angle with respect to the direction perpendicular to the extension/contraction direction of the inclined side 33b or the inclined side 34b is large in order to detect the angular deviation of the arm 27.

When the left AWC sensor 26L and the right AWC sensor 26R are disposed in the transfer module 12, the AWC sensors 26R and 26L may be deviated from the designed positions. Further, due to the slight deformation of the transfer module 12 by depressurization, the left AWC sensor 26L and the right AWC sensor 26R may be inclined, and the irradiation direction of the left laser beam L and the right laser beam L may be deviated from the designed directions. Further, due to the deviation of the irradiation directions of the left laser beam L and the right laser beam L, the amount of the left laser beam L and the right laser beam L that reach the left protrusion 33 and the right protrusion 34 of the pick 30 may be insufficient. In that case, the absolute values of the measured shielding start position A, shielding end position B, shielding start position C, and shielding end position D include errors.

Here, as described above, when the angular deviation of the arm 27 has not occurred, the shielding start position A of the left protrusion 33 and the shielding start position C of the right protrusion 34 coincide with each other, and the shielding end position of the left protrusion 33 B and the shielding end position D of the right protrusion 34 coincide with each other.

However, when the left AWC sensor 26L and the right AWC sensor 26R are deviated or tilted from the designed arrangement position, the shielding start position A and the shielding start position C do not coincide with each other because they both have errors. Further, the shielding end position B and the shielding end position D do not coincide with each other because they both have errors. For example, even though the shielding start position A is 714 mm, the shielding start position C may be 716 mm, and even though the shielding end position B is 716 mm, the shielding end position D may be 718 mm. If the absolute values of the shielding start position A, the shielding end position B, the shielding start position C, and the shielding end position D, which include errors, are used for calculating the magnitude T of the angle deviation of the arm 27, it is not possible to accurately obtain the magnitude T of the angular deviation.

In contrast, in the present embodiment, the absolute values of the shielding start position A, the shielding end position B, the shielding start position C, and the shielding end position D are not used for calculating the magnitude T of the angular deviation of the arm 27. Instead, as shown in Eq. (8), the magnitude T of the angular deviation of the arm 27 is calculated using relative values of the extension amount of the arm 27, such as the left shielding distance (B−A) or the right shielding distance (D−C).

Since the shielding start position A and the shielding end position B are measured by the same left AWC sensor 26L, they both have errors caused by the left AWC sensor 26L. Accordingly, in the left shielding distance (B−A), the errors caused by the left AWC sensor 26L are eliminated. Therefore, the left shielding distance (B−A) does not have errors even if the left AWC sensor 26L is deviated or tilted from the designed arrangement position.

Further, since the shielding start position C and the shielding end position D are also measured by the same right AWC sensor 26R, they both have errors caused by the right AWC sensor 26R. Accordingly, also in the right shielding distance (D−C), the errors caused by the right AWC sensor 26R are eliminated. Therefore, the right shielding distance (D−C) also does not have errors even if the right AWC sensor 26R is deviated or tilted from the designed arrangement position.

In other words, in the method for calculating the magnitude T of the angular deviation of the arm 27, which is shown in Eq. (8), the magnitude T of the angular deviation of the arm 27 is calculated from the left shielding distance (B−A) or the right shielding distance (D−C) in which the errors caused by the left AWC sensor 26L or the right AWC sensor 26R are eliminated. Accordingly, it is possible to accurately obtain the magnitude T of the angular deviation.

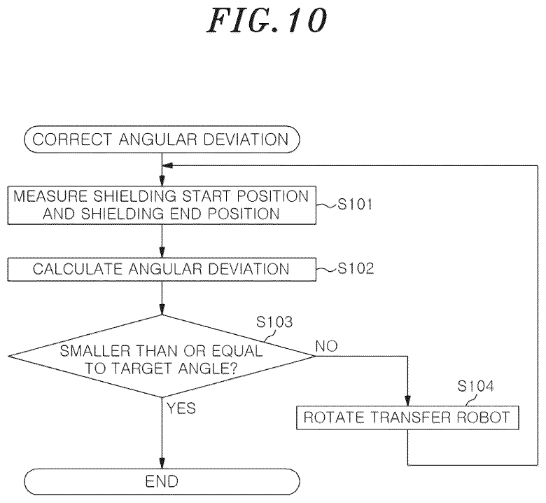

FIG. 10 is a flowchart illustrating a process for correcting the angular deviation of the arm 27, as a method for teaching a transfer robot, which is an embodiment of the technique of the present disclosure. For example, this correction process is executed by the controller 15 before various decompression processes are performed on the wafer W, which is after the transfer robot 23 is disposed in the transfer module 12 and the transfer module 12 is decompressed.

First, after the transfer module 12 is decompressed, the arm 27 is extended so that the laser beam L of the left AWC sensor 26L intersects with the left protrusion 33 of the left pick 30 and the laser beam L of the right AWC sensor 26R intersects the right protrusion 34 of the right pick 30, thereby measuring the shielding start positions A and C and the shielding end positions B and D (step S101).

Next, the left shielding distance (B−A) is calculated from the measured shielding start position A and the measured shielding end position B, and the right shielding distance (D−C) is calculated from the measured shielding start position C and the measured shielding end position D. Thereafter, the magnitude T of the angular deviation of the arm 27 is calculated based on Eq. (8) (step S102).

Next, it is determined whether or not the calculated magnitude T of the angular deviation of the arm 27 is smaller than or equal to a target angle (step S103). Then, if the calculated magnitude T of the angular deviation of the arm 27 is smaller than or equal to the target angle, this process is ended.

On the other hand, if the calculated magnitude T of the angular deviation of the arm 27 is larger than the target angle, the arm 27 is rotated around the rotation axis Z to eliminate the calculated magnitude T of the angular deviation of the arm 27 (step S104), and the process returns to step S101. Further, in step S104, the direction of the angular deviation of the arm 27 is determined by comparing the right shielding distance (D−C) and the left shielding distance (B−A), and the rotation direction of the arm 27 is determined.

In accordance with the present embodiment, the left AWC sensor 26L measures the shielding start position A and the shielding end position B of the left protrusion 33 of the pick 30, and the right AWC sensor 26R measures the shielding start position C and the shielding end position D of the right protrusion 34 of the pick 30. Then, the magnitude T of the angular deviation of the arm 27 can be calculated based on the right shielding distance (D−C) and the left shielding distance (B−A). Therefore, in the case of obtaining the magnitude T of the angular deviation of the arm 27, an operator does not need to visually examine the angular deviation of the arm, and it is unnecessary to prepare a wafer for alignment. Accordingly, it is possible to eliminate the angular deviation of the arm 27 without efforts.

In particular, since the left AWC sensor 26L and the right AWC sensor 26R are provided in advance in the substrate processing system 10, additional costs for eliminating the angular deviation of the arm 27 can be suppressed.

Further, in the present embodiment, the shielding start position A, the shielding end position B, the shielding start position C, and the shielding end position D are measured after the transfer module 12 is decompressed, so that the angular deviation of the arm 27 is eliminated. Accordingly, in the case of performing various decompression processes on the wafer W after the angular deviation of the arm 27 is eliminated, the angular deviation of the arm 27 and the deviation or tilting of the left AWC sensor 26L and the right AWC sensor 26R from the designed arrangement positions do not additionally occur. Therefore, it is possible to save the efforts of re-executing the process for correcting the angular deviation of the arm 27.

While the embodiments of the present disclosure have been described, the present disclosure is not limited to the above-described embodiments, and various modifications and changes can be made without departing from the scope of the gist thereof.

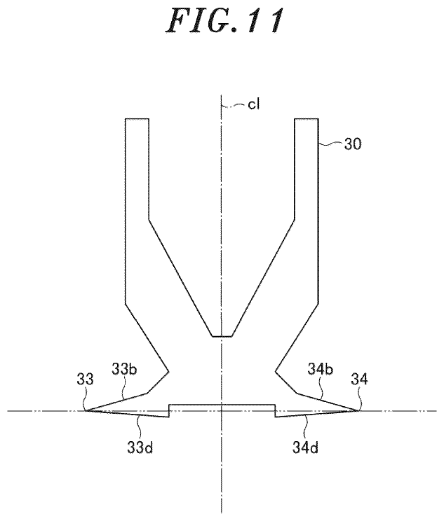

For example, the left protrusion 33 or the right protrusion 34 of the pick 30 has only one inclined side. However, the left protrusion 33 or the right protrusion 34 may have two inclined sides. For example, as shown in FIG. 11, the left protrusion 33 of the pick 30 may include the inclined side 33b, and may further include, instead of the rear end side 33a, an inclined side 33d intersecting obliquely with the direction (see dashed double-dotted line in FIG. 11) perpendicular to the extension/contraction direction. Further, the right protrusion 34 may include the inclined side 34b, and may further include, instead of the rear end side 34a, an inclined side 34d intersecting obliquely with the direction perpendicular to the extension/contraction direction.

Also in this case, the thickness of the left protrusion 33 or the right protrusion 34 changes along the direction perpendicular to the extension/contraction direction. Therefore, when the angular deviation of the arm 27 has occurred, the left shielding distance (B−A) or the right shielding distance (D−C) changes. Accordingly, also in the case of using the pick 30 shown in FIG. 11, the magnitude T of the angular deviation of the arm 27 can be calculated by measuring the shielding start position A, the shielding end position B, the shielding start position C, and the shielding end position D.

Further, in the present embodiment, the magnitude T of the angular deviation of the arm 27 was calculated by measuring the shielding start position A and the shielding end position B of the left protrusion 33 of the right pick 30, and the shielding start position C and the shielding end position D of the right protrusion 34 of the left pick 30.

However, the magnitude T of the angular deviation of the arm 27 may also be calculated by measuring the shielding start position A and the shielding end position B of the left protrusion 33 of only one of the right pick 30 and the left pick 30, and the shielding start position C and the shielding end position D of the right protrusion 34 of the same pick 30. However, in this case, in Eq. (8), the inter-sensor distance E is not the pitch between the left AWC sensor 26L and the right AWC sensor 26R, but the pitch between the AWC sensor 26L and AWC sensor 26R corresponding to one pick 30.

Further, the technique of the present disclosure can be applied even when the transfer robot 23 includes only one pick 30. In this case, the magnitude T of the angular deviation of the arm 27 can be calculated by measuring the shielding start position A and the shielding end position B of the left protrusion 33 of one pick 30, and the shielding start position C and the shielding end position D of the right protrusion 34 of the same pick 30. However, also in this case, in Eq. (8), the inter-sensor distance E is not the pitch between the left AWC sensor 26L and the right AWC sensor 26R, but the pitch between the AWC sensor 26L and AWC sensor 26R corresponding to one pick 30.

1. A method for teaching a transfer robot, wherein the transfer robot includes an arm that rotates around a vertical rotation axis and extends/contracts on a horizontal plane perpendicular to the rotation axis, and a substrate support attached to the arm,
wherein the arm has a first protrusion disposed on a left side with respect to an extension/contraction direction of the arm, and a second protrusion disposed on a right side with respect to the extension/contraction direction of the arm,
the first protrusion and the second protrusion move together with the substrate support by extension/contraction of the arm,
a first sensor is disposed on the left side with respect to the extension/contraction direction, and a second sensor is disposed on the right side with respect to the extension/contraction direction, and
the first protrusion intersects with detection light of the first sensor during the extension/contraction of the arm, and the second protrusion intersects with detection light of the second sensor during the extension/contraction of the arm,
the method comprising:
calculating angular deviation of the arm around the rotation axis based on an extension amount of the arm at the time when the second protrusion intersects with the detection light of the second sensor, and the extension amount of the arm at the time when the first protrusion intersects the detection light of the first sensor; and
rotating the arm around the rotation axis to eliminate the calculated angular deviation.

2. The method for teaching the transfer robot of claim 1, wherein the first protrusion and the second protrusion have symmetrical shapes with respect to the extension/contraction direction, and the first sensor and the second sensor are arranged at symmetrical positions with respect to the extension/contraction direction.

3. The method for teaching the transfer robot of claim 1, wherein the first protrusion has a first inclined side intersecting obliquely with a direction perpendicular to the extension/contraction direction on the horizontal plane, and the second protrusion has a second inclined side intersecting obliquely with the direction perpendicular to the extension/contraction direction on the horizontal plane.

4. The method for teaching the transfer robot of claim 1, wherein the angular deviation of the arm around the rotation axis is calculated based on a first distance that is a movement distance of the arm from the start of the intersection between the first protrusion and the detection light of the first sensor to the end of intersection between the first protrusion and the detection light of the first sensor during the extension/contraction of the arm, and a second distance that is a movement distance of the arm from the start of the intersection between the second protrusion and the detection light of the second sensor to the end of the intersection between the second protrusion and the detection light of the second sensor during the extension/contraction of the arm.

5. The method of teaching the transfer robot of claim 4, wherein a direction of the angular deviation of the arm around the rotation axis is determined based on the first distance and the second distance.

6. The method for teaching the transfer robot of claim 4, wherein when the extension amount of the arm at the time when the intersection between the first protrusion and the detection light of the first sensor is ended on the assumption that there is no angular deviation of the arm around the rotation axis is set to an assumed extension amount of the first arm, and the extension amount of the arm at the time when the intersection between the second protrusion and the detection light of the second sensor is ended on the assumption that there is no angular deviation of the arm around the rotation axis is set to an assumed extension amount of the second arm, the angular deviation of the arm around the rotation axis is calculated by calculating the assumed extension amount of the first arm from the angular deviation of the arm around the rotation axis and an actually measured extension amount of the arm at the time when the intersection between the first protrusion and the detection light of the first sensor is ended, and calculating the assumed extension amount of the second arm from the angular deviation of the arm around the rotation axis and an actually measured extension amount of the arm at the time when the intersection between the second protrusion and the detection light of the second sensor is ended.

7. The method for teaching the transfer robot of claim 1, wherein the transfer robot is disposed in a substrate transfer chamber, and
the extension amount of the arm at the time when the first protrusion intersects with the detection light of the first sensor and the extension amount of the arm at the time when the second protrusion intersects with the detection light of the second sensor are measured when the substrate transfer chamber is decompressed.

8. The method of teaching the transfer robot of claim 1, wherein the first sensor and the second sensor are provided in advance in a substrate processing system so that the transfer robot detects a substrate transferred by the substrate support and the arm.

9. A substrate processing system comprising:
a substrate processing chamber where a substrate is processed;
a substrate transfer chamber having therein a transfer robot configured to load/unload the substrate into/from the substrate processing chamber; and
a controller,
wherein the transfer robot includes an arm that rotates around a vertical rotation axis and extends/contracts on a horizontal plane perpendicular to the rotation axis, and a substrate support attached to the arm,
the arm has a first protrusion disposed on a left side with respect to an extension/contraction direction of the arm, and a second protrusion disposed on a right side with respect to the extension/contraction direction of the arm,
the first protrusion and the second protrusion move together with the substrate support by extension/contraction of the arm,
a first sensor is disposed on the left side with respect to the extension/contraction direction, and a second sensor is disposed on the right side with respect to the extension/contraction direction,
the first protrusion intersects with detection light of the first sensor during the extension/contraction of the arm, and the second protrusion intersects with detection light of the second sensor during the extension/contraction of the arm, and
the controller calculates angular deviation of the arm around the rotation axis based on the extension amount of the arm at the time when the first protrusion intersects with detection light of the first sensor, and the extension amount of the arm at the time when the second protrusion intersects with detection light of the second sensor, and rotates the arm around the rotation axis to eliminate the calculated angular deviation.
